(19) United States
(12) Patent Application Publication
(10) Pub. No.: US 2022/0349063 A1
(43) Pub. Date: Nov. 3, 2022

(54) SEMICONDUCTOR MANUFACTURING APPARATUS HAVING TRANSFER UNIT AND METHOD FOR FORMING SEMICONDUCTOR DEVICE

(71) Applicant: SAMSUNG ELECTRONICS CO., LTD., Suwon-si (KR)

(72) Inventors: Sejin Yoo, Asan-si (KR); Hyungjun Jang, Asan-si (KR)

(21) Appl. No.: 17/510,496

(22) Filed: Oct. 26, 2021

(30) Foreign Application Priority Data
Apr. 28, 2021 (KR) 10-2021-0054936

(51) Int. Cl. C23C 28/00; H01L 21/677; H01L 21/687; C23C 16/27; C23C 16/455; C23C 16/458

(52) U.S. Cl. CPC C23C 28/343; H01L 21/67742; H01L 21/687; C23C 16/27; C23C 16/45536; C23C 16/4583

(57) ABSTRACT

A semiconductor manufacturing apparatus includes a process chamber. A chuck is disposed in the process chamber. The chuck is configured to hold a substrate thereon. A transfer unit is adjacent to the process chamber. The transfer unit includes a transfer hand configured to transfer the substrate. A slow discharge layer is disposed on a first surface of the transfer hand. The slow discharge layer is configured to discharge static electricity charged in the substrate.

### CROSS-REFERENCE TO THE RELATED APPLICATION

This application claims priority under 35 U.S.C. § 119 to Korean Patent Application No. 10-2021-0054936, filed on Apr. 28, 2021 in the Korean Intellectual Property Office, the disclosure of which is incorporated by reference in its entirety herein.

### 1. Technical Field

Embodiments of the present inventive concept relate to a semiconductor manufacturing apparatus having a transfer unit and a semiconductor device formation method using the same.

### 2. Discussion of Related Art

Some semiconductor manufacturing apparatuses include a process chamber, a chuck to hold a substrate in the process chamber, and a transfer device for transferring the substrate to an interior of the process chamber or to carry the substrate outside of the process chamber from the process chamber. The transfer device may come close to the substrate or may directly contact the substrate. Therefore, static electricity that is charged in the substrate may be discharged through the transfer device. Internal circuits of the substrate may be damaged by the discharge of the static electricity.

### SUMMARY

Embodiments of the present inventive concept may provide a semiconductor manufacturing apparatus that prevents the occurrence of failure caused by static electricity and a semiconductor device formation method using the same.

According to an embodiment of the present inventive concept, a semiconductor manufacturing apparatus includes a process chamber. A chuck is disposed in the process chamber. The chuck is configured to hold a substrate thereon. A transfer unit is adjacent to the process chamber. The transfer unit includes a transfer hand configured to transfer the substrate. A slow discharge layer is disposed on a first surface of the transfer hand. The slow discharge layer is configured to discharge static electricity charged in the substrate.

According to an embodiment of the present inventive concept, a semiconductor device formation method includes loading the substrate on the chuck of a semiconductor manufacturing apparatus by the transfer hand. A surface modification process is performed for one surface of the substrate in the process chamber. The substrate is transferred to an outside of the process chamber using the transfer hand after the surface modification process is performed.

According to an embodiment of the present inventive concept, a transfer unit includes a transfer hand having a first surface and a second surface opposing each other. A slow discharge layer is on the first surface. The slow discharge layer is configured to discharge static electricity. A protrusion is on the second surface. An arm is on the protrusion. A connector directly contacts the arm and the protrusion.

According to an embodiment of the present inventive concept, a transfer unit includes a transfer hand having a first surface and a second surface opposing each other. A protrusion is on the second surface. An arm is on the protrusion. A connector directly contacts the arm and the protrusion. The transfer hand comprises a dissipative material layer.

### BRIEF DESCRIPTION OF THE DRAWINGS

FIG. 1 is a plan view of a semiconductor manufacturing apparatus and an operating method thereof according to embodiments of the present inventive concept.

FIG. 2 is a perspective view showing a configuration of FIG. 1 according to an embodiment of the present inventive concept.

FIG. 3 is a perspective view showing a portion of a transfer unit according to an embodiment of the present inventive concept.

FIG. 4 is a plan view showing a portion of the transfer unit of FIG. 3 according to an embodiment of the present inventive concept.

FIG. 5 is a plan view showing a portion of the transfer unit of FIG. 3 according to an embodiment of the present inventive concept.

FIGS. 6 to 10 are cross-sectional views of a transfer unit according to embodiments of the present inventive concept.

FIGS. 11 to 13, and FIGS. 15, 17 and 18 are cross-sectional views showing a semiconductor manufacturing apparatus, an operating method thereof, and semiconductor device formation methods according to embodiments of the present inventive concept.

FIG. 14 is an enlarged cross-sectional view showing a portion of the semiconductor manufacturing apparatus, the operating method thereof, and semiconductor device formation methods of FIG. 13 according to an embodiment of the present inventive concept.

FIG. 16 is an enlarged cross-sectional view showing a portion of the semiconductor manufacturing apparatus, the operating method thereof, and semiconductor device formation methods of FIG. 15 according to an embodiment of the present inventive concept.

### DETAILED DESCRIPTION OF EMBODIMENTS

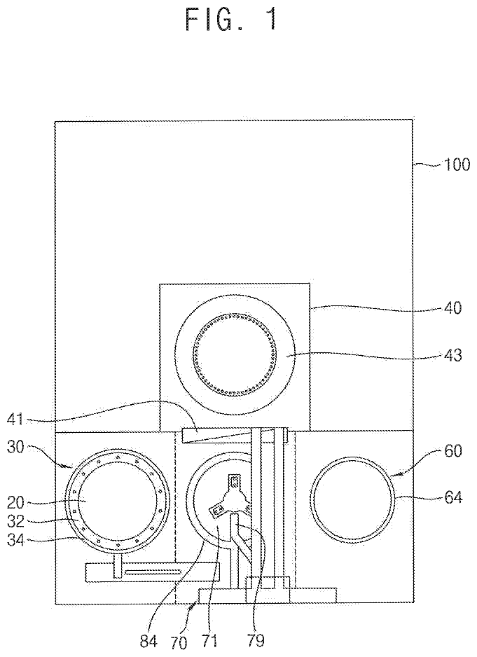

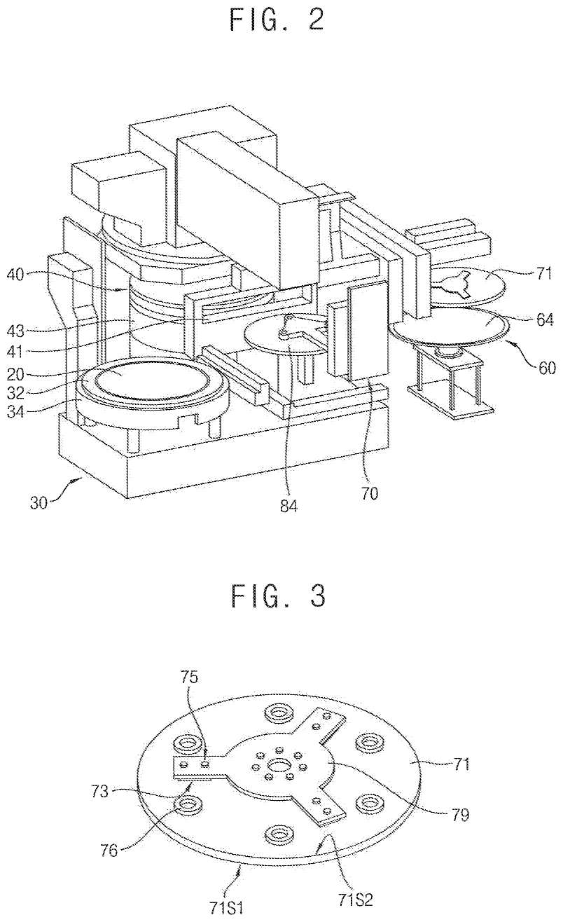

FIG. 1 is a plan view of a semiconductor manufacturing apparatus 100 and an operating method thereof according to embodiments of the present inventive concept. FIG. 2 is a perspective view showing a configuration of FIG. 1. In an embodiment, the semiconductor manufacturing apparatus 100 may include a substrate backside modification device for a back lapping process.

Referring to FIGS. 1 and 2, the semiconductor manufacturing apparatus 100 according to embodiments of the present inventive concept may include a preparation unit 30, a process chamber 40, a release unit 60, and a transfer unit 70. The preparation unit 30 may include a carrier 32, on which a substrate 20 is seated, and a preparation stage 34. The process chamber 40 may include an entrance 41. A chuck 43 may be disposed in the process chamber 40. The release unit 60 may include a release stage 64. The transfer unit 70 may include a transfer hand 71, an arm 79, and a lower stage 84.

The preparation unit 30, the release unit 60 and the transfer unit 70 may be disposed adjacent to the process chamber 40. In an embodiment, the preparation unit 30 and the release unit 60 may be disposed to oppose each other. The transfer unit 70 may be disposed between the preparation unit 30 and the release unit 60 and may also be positioned adjacent to the entrance 41.

The carrier 32 may be disposed on the preparation stage 34. The substrate 20 may be loaded on the carrier 32. In an embodiment, the preparation unit 30 may function to dry the substrate 20. For example, the preparation unit 30 may include a device for injecting a gas having a normal temperature or a higher temperature than normal temperature toward the substrate 20. In an embodiment, the preparation stage 34 may include a heater for drying the substrate 20.

However, embodiments of the present inventive concept are not limited thereto. For example, in an embodiment, the carrier 32 may be omitted and the substrate 20 may be loaded directly on the preparation stage 34.

The carrier 32 and the substrate 20 may be transferred onto the lower stage 84 of the transfer unit 70. The arm 79 may be connected to the transfer hand 71. The substrate 20 may be transferred onto the chuck 43 via the entrance 41 by the transfer hand 71 and the arm 79. In an embodiment, the chuck 43 may include an electrostatic chuck. The chuck 43 may be configured to hold the substrate 20 thereon (e.g., be seated thereon). A predetermined process may be performed on the substrate 20 seated on the chuck 43 in the process chamber 40. After the process is performed on the substrate 20, the substrate 20 may be transferred onto the release stage 64 of the release unit 60 via the entrance 41 by the transfer hand 71 and the arm 79 of the transfer unit 70. The release unit 60 may function to align a direction of the substrate 20. For example, the release stage 64 may function to rotate the substrate 20 to align with a predetermined direction.

FIG. 3 is a perspective view showing a portion of a transfer unit according to embodiments of the present inventive concept.

Referring to FIG. 3, the transfer unit according to embodiments of the present inventive concept may include a transfer hand 71, a plurality of protrusions 73, a plurality of connectors 75, a plurality of vacuum connection ports 76, and an arm 79. The transfer hand 71 may include a first surface 71S1 and a second surface 71S2 opposing each other (e.g., in a thickness direction of the transfer hand 71).

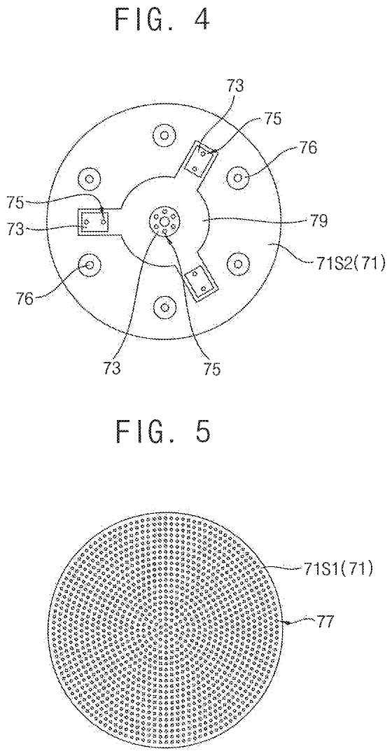

FIG. 4 is a plan view showing a portion of FIG. 3.

Referring to FIG. 4, the plurality of protrusions 73, the plurality of connectors 75, the plurality of vacuum connection ports 76 and the arm 79 may be disposed on the second surface 71S2 of the transfer hand 71. For example, the second surface 71S2 of the transfer hand 71 may be an upper surface.

FIG. 5 is a plan view showing a portion of FIG. 3.

Referring to FIG. 5, a plurality of vacuum holes 77 may be disposed at the first surface 71S1 of the transfer hand 71. For example, the first surface 71S1 of the transfer hand 71 may be a bottom surface.

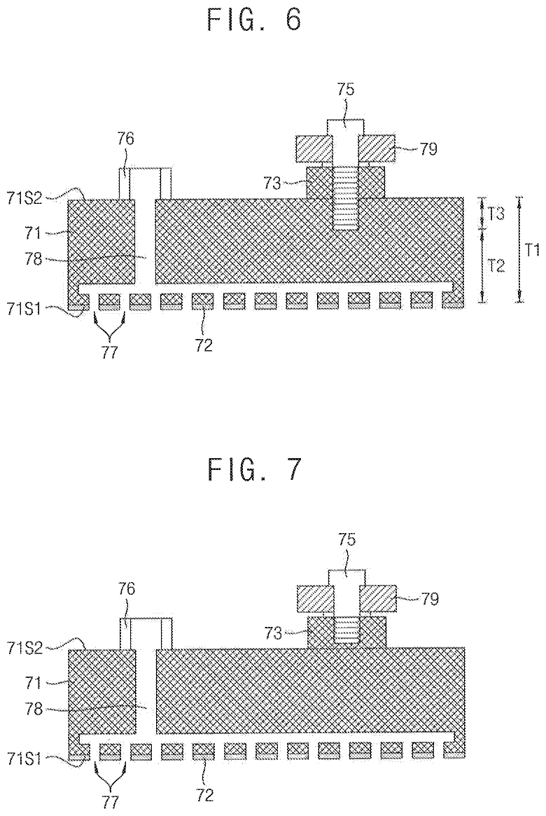

FIGS. 6 to 10 are cross-sectional views of a transfer unit according to embodiments of the present inventive concept.

Referring to FIG. 6, the transfer unit according to embodiments of the present inventive concept may include a transfer hand 71, a slow discharge layer 72, a protrusion 73, a connector 75, a vacuum connection port 76, a plurality of vacuum holes 77, a plurality of distribution passages 78, and an arm 79. The transfer hand 71 may include a first surface 71S1 and a second surface 71S2 opposing each other.

Again referring to FIGS. 1 to 6, the transfer unit 70 may include the transfer hand 71, the slow discharge layer 72, the plurality of protrusions 73, the plurality of connectors 75, the plurality of vacuum connection ports 76, the plurality of vacuum holes 77, the plurality of distribution passages 78, the arm 79, and the lower stage 84. The first surface 71S1 may correspond to a bottom surface of the transfer hand 71. The second surface 71S2 may correspond to a top surface of the transfer hand 71.

The plurality of vacuum connection ports 76 may be disposed on the second surface 71S2 of the transfer hand 71. In an embodiment, the plurality of vacuum connection ports 76 may be connected to an external vacuum generator via a vacuum line. The external vacuum generator may generate a suction force and may operate as known in the art. The plurality of vacuum holes 77 may be exposed at the first surface 71S1 of the transfer hand 71. The plurality of distribution passages 78 may be disposed between the plurality of vacuum holes 77 and the plurality of vacuum connection ports 76 in a thickness direction of the transfer hand 71 and may communicate with the plurality of vacuum holes 77 and the plurality of vacuum connection ports 76 while extending through an interior of the transfer hand 71.

The substrate 20 may be suctioned onto the first surface 71S1 of the transfer hand 71. In an embodiment, the transfer hand 71 may have a greater horizontal width than the substrate 20. In an embodiment, the transfer hand 71 may have a similar shape to the substrate 20. For example, the transfer hand 71 may have a disc shape having a greater diameter than the substrate 20. However, embodiments of the present inventive concept are not limited thereto. The transfer hand 71 may have a first thickness T1. In an embodiment, the first thickness T1 may be in a range of about 0.5 cm to about 3 cm. The transfer hand 71 may include a conductive material layer, a dissipative material layer, or a combination thereof. In an embodiment, the transfer hand 71 may include a material layer having resistivity of about 100 Ωcm to about 1,000,000,000 Ωcm.

In an embodiment, the transfer hand 71 may include a dissipative material layer. In an embodiment, the transfer hand 71 may include a material layer having resistivity of about 10,000 Ωcm to about 1,000,000,000 Ωcm. The transfer hand 71 may function to slowly discharge static electricity of the substrate 20. For example, the discharge speed of static electricity charged in the substrate 20 may be reduced by the transfer hand 71.

The slow discharge layer 72 may be disposed on the first surface 71S1 of the transfer hand 71. For example, in an embodiment, an upper surface of the slow discharge layer 72 may directly contact the first surface 71S1 of the transfer hand 71. The plurality of vacuum holes 77 may extend into the transfer hand 71 while extending through the slow discharge layer 72. The substrate 20 may be suctioned onto the slow discharge layer 72 by suction force from the external vacuum generator applied through the plurality of vacuum connection ports 76, the plurality of distribution passages 78 and the plurality of vacuum holes 77. The slow discharge layer 72 may directly contact the substrate 20. The slow discharge layer 72 may be interposed between the first surface 71S1 of the transfer hand 71 and the substrate 20. The slow discharge layer 72 may contact the first surface 71S1 of the transfer hand 71 and the substrate 20. For example, a lower surface of the slow discharge layer 72 may directly contact the substrate 20 and an upper surface of the slow discharge layer 72 may directly contact the first surface 7151 of the transfer hand 71.

The slow discharge layer 72 may include a material having greater resistivity than the transfer hand 71. For example, in an embodiment, the slow discharge layer 72 may include a material layer having resistivity in a range of about 100,000 Ωcm to about 1,000,000,000 Ωcm. For example, in an embodiment, the slow discharge layer 72 may include a diamond-like carbon (DLC) coating layer. However, embodiments of the present inventive concept are not limited thereto. The slow discharge layer 72 may be thinner than the transfer hand 71. In an embodiment, the slow discharge layer 72 may have a thickness in a range of about 1 μm to about 30 μm. The slow discharge layer 72 may function to slowly discharge static electricity of the substrate 20. The discharge speed of static electricity charged in the substrate 20 may be reduced by the slow discharge layer 72.

Each of the plurality of protrusions 73 may be bonded to the second surface 71S2. In an embodiment, each of the plurality of protrusions 73 may have an integrated structure that extends in continuity with the transfer hand 71. For example, in an embodiment, each of the plurality of protrusions 73 may include substantially the same material as the transfer hand 71.

The arm 79 may be disposed on the plurality of protrusions 73. The plurality of connectors 75 may extend into the transfer hand 71 while extending through the arm 79 and the plurality of protrusions 73, respectively. For example, as shown in FIG. 6, the plurality of connectors 75 may extend entirely through the thicknesses of the arm 79, the protrusion 73 and the second surface 71S2 of the transfer hand 71 and may extend partially through the thickness of the transfer hand 71 towards the first surface 71S1 of the transfer hand 71. The minimum distance between the first surface 71S1 and the plurality of connectors 75 may be a second thickness T2. The minimum distance between a lowermost end of the plurality of connectors 75 and a horizontal line passing the second surface 71S2 may be a third thickness T3.

In an embodiment, the second thickness T2 may be greater than about half of the first thickness T1. The third thickness T3 may be smaller than about half of the first thickness T1. For example, in an embodiment, the second thickness T2 may be in a range of about 5 mm to about 30 mm. The second thickness T2 may be about 7 mm or more. The second thickness T2 may be in a range of about 7 mm to about 30 mm. The second thickness T2 may be about 7 mm.

Static electricity charged in the substrate 20 may be discharged via the slow discharge layer 72, the transfer hand 71, the plurality of connectors 75, and the arm 79. An increase in the second thickness T2 may serve to lengthen a discharge path of static electricity charged in the substrate 20. An increase in the second thickness T2 may serve to increase the discharge path resistance of static electricity charged in the substrate 20. By virtue of such an increase in the second thickness T2, the discharge speed of static electricity charged in the substrate 20 may be reduced.

In an embodiment, the plurality of connectors 75 may include a bolt, a rivet, a joint, or a combination thereof. However, embodiments of the present inventive concept are not limited thereto. The plurality of connectors 75 may include a dissipative material, an insulating material, or a combination thereof. For example, in an embodiment, the plurality of connectors 75 may include semi-crystalline thermoplastics such as a polyetheretherketone (PEEK) resin. The plurality of connectors 75 may function to slowly discharge static electricity of the substrate 20 or to block a discharge path of the static electricity. Due to the plurality of connectors 75, the discharge speed of static electricity charged in the substrate 20 may be reduced, or discharge thereof may be blocked.

Referring to FIG. 7, a connector 75 may extend into a protrusion 73 while extending through an arm 79. A lowermost end of the connector 75 may be disposed at a higher level than the second surface 71S2 of the transfer hand 71. For example, the connector 75 may extend only partially through the protrusion 73 and a bottom surface of the connector 75 may be disposed above the bottom surface of the protrusion. The minimum distance between a first surface 71S1 and the connector 75 may be greater than the thickness of a transfer hand 71.

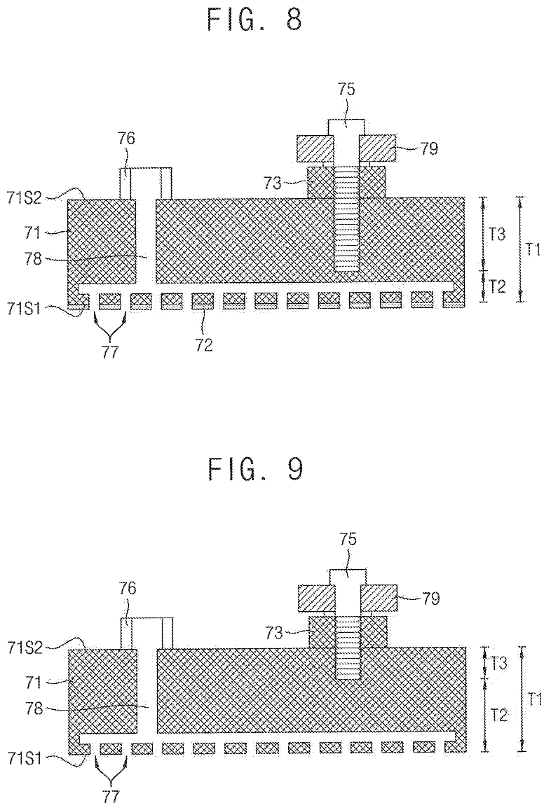

Referring to FIG. 8, a connector 75 may extend into a transfer hand 71 while extending through an arm 79 and a protrusion 73. The lowermost end of the connector 75 in the embodiment of FIG. 8 may extend closer to the first surface 71S1 of the transfer hand 71 than in the embodiments of FIGS. 6-7. For example, in an embodiment, a second thickness T2 may be smaller than about half of a first thickness T1. A third thickness T3 may be greater than about half of the first thickness T1.

Referring to FIG. 9, a transfer unit according to an embodiment of the present inventive concept may include a transfer hand 71, a protrusion 73, a connector 75, a vacuum connection port 76, a plurality of vacuum holes 77, a plurality of distribution passages 78, and an arm 79. The transfer hand 71 may include a first surface 71S1 and a second surface 71S2 opposing each other. In the embodiment shown in FIG. 9, the slow discharge layer (“72” in FIG. 6) may be omitted and the first surface 71S1 may be exposed.

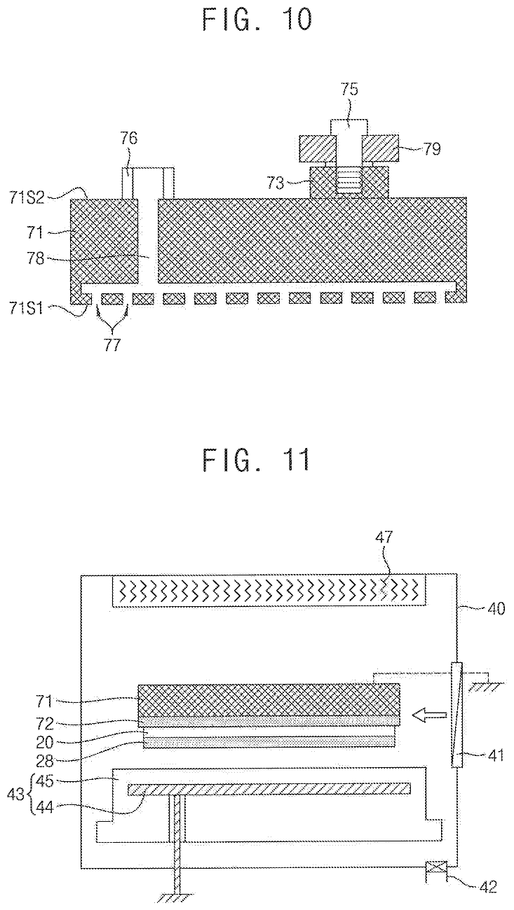

Referring to FIG. 10, a connector 75 may extend into a protrusion 73 while extending through an arm 79. A lowermost end of the connector 75 may be disposed at a higher level than the second surface 71S2. For example, the connector 75 may extend only partially through the protrusion 73 and a bottom surface of the connector 75 may be disposed above the bottom surface of the protrusion. In the embodiment shown in FIG. 10, the slow discharge layer (“72” in FIG. 6) may be omitted and the first surface 71S1 may be exposed.

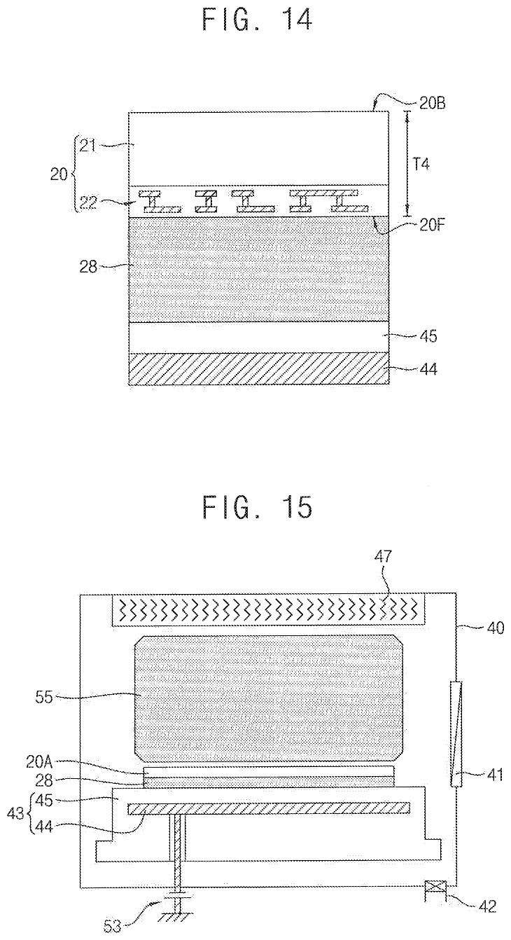

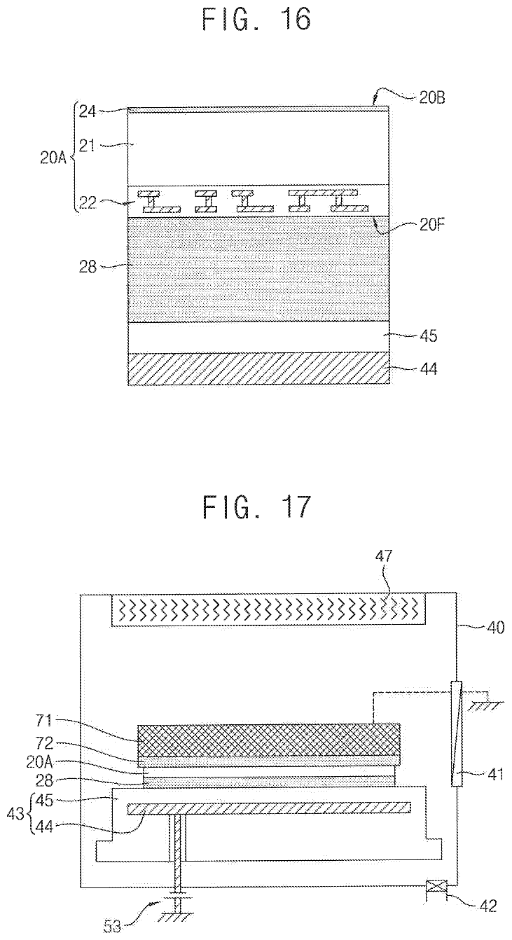

FIGS. 11 to 13, and FIGS. 15, 17 and 18 are cross-sectional views of a semiconductor manufacturing apparatus, an operating method thereof, and semiconductor device formation methods according to embodiments of the present inventive concept. FIG. 14 is an enlarged view showing a portion of FIG. 13. FIG. 16 is an enlarged view showing a portion of FIG. 15.

Referring to FIG. 11, an entrance 41 may be disposed at one surface (e.g., a side wall) of a process chamber 40. An exhaust port 42 may be disposed at one surface (e.g., a bottom wall) of the process chamber 40. A chuck 43 may be disposed in an interior (e.g., a lower region) of the process chamber 40. In an embodiment, the chuck 43 may include an electrostatic chuck. The chuck 43 may include a lower electrode 44 and a dielectric layer 45. The dielectric layer 45 may cover the lower electrode 44, such as upper, lower and lateral side surfaces of the lower electrode 44. In an embodiment, a sputtering process may be performed in the process chamber 40. A plasma generator 47 may be disposed in an interior (e.g., an upper region of the interior) of the process chamber 40. The plasma generator 47 may include a plurality of constituent elements such as a gas inlet and an upper electrode as known in the art.

Although the transfer unit 70 may include various configurations, as described with reference to FIGS. 1 to 10, the transfer unit 70 will be described mainly in conjunction with the transfer hand 71 and the slow discharge layer 72, for simplicity of description.

The transfer hand 71 may function to pick up a substrate 20 from an outside of the process chamber 40 and to transfer the substrate 20 into the interior of the process chamber 40 via the entrance 41. In an embodiment, a protective film 28 may be attached to one surface of the substrate 20. In an embodiment, the protective film 28 may include a backgrind tape or a lamination tape. However, embodiments of the present inventive concept are not limited thereto. The slow discharge layer 72 may be disposed between the transfer hand 71 and the substrate 20. The slow discharge layer 72 may directly contact the transfer hand 71 and the substrate 20. Each of the lower electrode 44 and the transfer hand 71 may be in a grounded state.

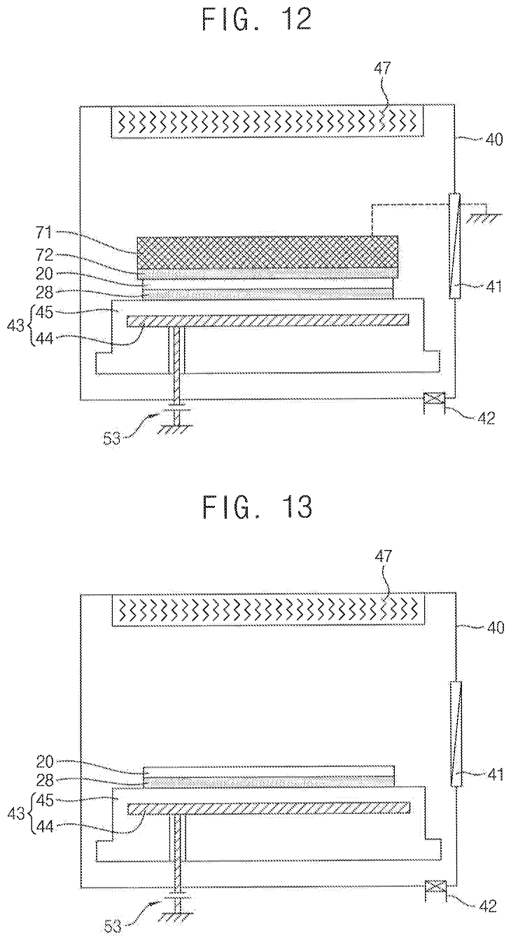

Referring to FIG. 12, the substrate 20 may be seated on the chuck 43. A first power 53 may be applied to the lower electrode 44 to hold the substrate 20 on the chuck 43. In an embodiment, the first power 53 may be about −1,700 V. However, embodiments of the present inventive concept are not limited thereto. The protective film 28 may be disposed between the substrate 20 and the dielectric layer 45. The protective film 28 may directly contact the substrate 20 and the dielectric layer 45. Static electricity may be charged in the substrate 20 due to influence of the first power 53.

Referring to FIG. 13, the substrate 20 may be held on the chuck 43. One surface of the substrate 20 may be exposed in the process chamber 40. The transfer hand 71 and the slow discharge layer 72 may be positioned outside of the process chamber 40. Static electricity may be charged in the substrate 20 due to influence of the first power 53.

Referring to FIG. 14, the substrate 20 may include an original plate 21 and an active layer 22. In an embodiment, the original plate 21 may include a semiconductor substrate such as a monocrystalline silicon wafer. However, embodiments of the present inventive concept are not limited thereto. The active layer 22 may include a plurality of active/passive elements and an insulating layer. The substrate 20 may include a front surface 20F and a back surface 20B opposing each other (e.g., in a thickness direction of the substrate 20). The active layer 22 may be adjacent to the front surface 20F. The protective film 28 may be attached to the front surface 20F of the substrate 20. The protective film 28 may be disposed between the substrate 20 and the dielectric layer 45. The back surface 20B of the substrate 20 may be exposed in the process chamber 40.

In an embodiment, a backgrind process may be performed on the back surface 20B of the substrate 20 before the substrate 20 is loaded in the process chamber 40. The thickness of the substrate 20 may be reduced by the backgrind process. The substrate 20 may have a fourth thickness T4. In an embodiment, the fourth thickness T4 may be in a range of about 5 μm to about 100 μm. For example, in an embodiment, the fourth thickness T4 may be about 30 μm.

Referring to FIG. 15, a surface modification process may be performed on the back surface 20B of the substrate 20 in the process chamber 40 and, as such, a surface-modified substrate 20A may be formed. In an embodiment, the surface modification process may include a sputtering process such as an AR sputtering process. For example, a plasma 55 may be generated in the process chamber 40 using the plasma generator 47. During the performance of the surface modification process, the back surface 20B of the substrate 20 may be in direct contact with the plasma 55.

During performance of the surface modification process, static electricity may be charged in the surface-modified substrate 20A due to the influence of the first power 53 and the plasma 55.

Referring to FIG. 16, a surface layer 24 may be formed at the back surface 20B of the substrate 20 during the performance of the surface modification process. In an embodiment, the thickness of the surface layer 24 may be smaller than the thickness of the original plate 21. In an embodiment, the surface layer 24 may include a polycrystalline semiconductor (e.g., polysilicon), an amorphous semiconductor (e.g., amorphous silicon), or a combination thereof. The surface-modified substrate 20A may include the original plate 21, the active layer 22, and the surface layer 24. The original plate 21 may be maintained between the active layer 22 and the surface layer 24.

Referring to FIG. 17, the transfer hand 71 and the slow discharge layer 72 may be moved onto the surface-modified substrate 20A. The surface-modified substrate 20A may be suctioned onto the transfer hand 71 and the slow discharge layer 72 by the suction force of the external vacuum generator. The slow discharge layer 72 may directly contact the transfer hand 71 and the surface-modified substrate 20A.

Static electricity charged in the surface-modified substrate 20A may be discharged via the slow discharge layer 72 and the transfer hand 71. The slow discharge layer 72 and the transfer hand 71 may function to reduce the discharge speed of the static electricity charged in the surface-modified substrate 20A. Therefore, the occurrence of failure of the surface-modified substrate 20A may be prevented.

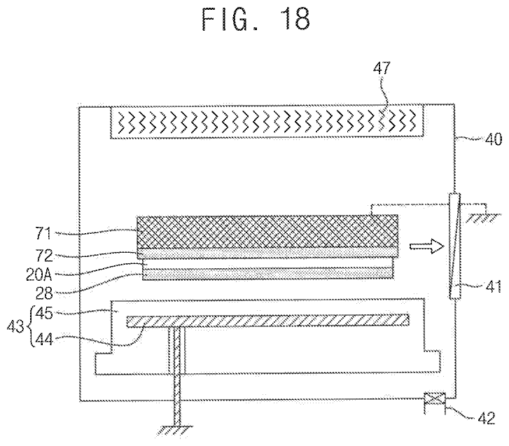

Referring to FIG. 18, the first power (“53” in FIG. 17) may be turned off. The lower electrode 44 may be grounded. The transfer hand 71 and the slow discharge layer 72 may function to pick up the surface-modified substrate 20A on the chuck 43 and to transfer the picked-up surface-modified substrate 20A to the outside of the process chamber 40 via the entrance 41.

In accordance with embodiments of the present inventive concept, a transfer unit including a transfer hand, a slow discharge layer and a connector may be provided. The transfer hand may include a dissipative material layer. The slow discharge layer may include a material having greater resistivity than the transfer hand. The connector may be disposed to be spaced apart from a substrate by a relatively large distance. The connector may include a dissipative material, an insulating material, or a combination thereof. Each of the transfer hand, the slow discharge layer, and the connector may function to reduce the discharge speed of static electricity charged in the substrate, to increase discharge path resistance of the static electricity, or to block a discharge path of the static electricity. A semiconductor manufacturing apparatus capable of preventing occurrence of failure caused by static electricity may be provided.

While embodiments of the present inventive concept have been described with reference to the accompanying drawings, it should be understood by those skilled in the art that various modifications may be made without departing from the scope of the present inventive concept and without changing essential features thereof. Therefore, the above-described embodiments should be considered in a descriptive sense only and not for purposes of limitation.

1. A semiconductor manufacturing apparatus comprising:
a process chamber;
a chuck disposed in the process chamber, the chuck configured to hold a substrate thereon; and
a transfer unit adjacent to the process chamber,
wherein the transfer unit comprises
a transfer hand configured to transfer the substrate, and
a slow discharge layer disposed on a first surface of the transfer hand, the slow discharge layer is configured to discharge static electricity charged in the substrate.

2. The semiconductor manufacturing apparatus according to claim 1, wherein the slow discharge layer comprises a material having a greater resistivity than a material of the transfer hand.

3. The semiconductor manufacturing apparatus according to claim 2, wherein the slow discharge layer comprises a material layer having a resistivity in a range of about 100,000 Ωcm to about 1,000,000,000 Ωcm.

4. The semiconductor manufacturing apparatus according to claim 1, wherein the slow discharge layer comprises a diamond-like carbon (DLC) coating layer.

5. The semiconductor manufacturing apparatus according to claim 1, wherein the transfer hand comprises a dissipative material layer.

6. The semiconductor manufacturing apparatus according to claim 1, wherein the transfer hand comprises a material layer having a resistivity in a range of about 10,000 Ωcm to about 1,000,000,000 Ωcm.

7. The semiconductor manufacturing apparatus according to claim 1, wherein the chuck comprises an electrostatic chuck.

8. The semiconductor manufacturing apparatus according to claim 1, wherein:
the transfer hand comprises a first surface adjacent to the substrate, and a second surface opposing the first surface; and
the transfer unit further comprises
a protrusion on the second surface,
an arm on the protrusion, and
a connector directly contacting the arm and the protrusion.

9. The semiconductor manufacturing apparatus according to claim 8, wherein the connector extends partially through a thickness of the transfer hand and extends entirely through thicknesses of the arm and the protrusion.

10. The semiconductor manufacturing apparatus according to claim 9, wherein:
the transfer hand has a first thickness;
a minimum distance between the first surface and the connector is a second thickness; and
the second thickness is greater than about half of the first thickness.

11. The semiconductor manufacturing apparatus according to claim 10, wherein the second thickness is in a range of about 7 mm to about 30 mm.

12. The semiconductor manufacturing apparatus according to claim 8, wherein the connector extends into the protrusion.

13. The semiconductor manufacturing apparatus according to claim 8, wherein the connector comprises at least one material selected from a dissipative material and an insulating material.

14. The semiconductor manufacturing apparatus according to claim 8, wherein the connector comprises a polyetheretherketone (PEEK) resin.

15. A semiconductor device formation method comprising:
loading the substrate on the chuck of the semiconductor manufacturing apparatus of claim 1 by the transfer hand;
performing a surface modification process for one surface of the substrate in the process chamber; and
transferring the substrate to an outside of the process chamber using the transfer hand after the surface modification process is performed.

16. The semiconductor device formation method according to claim 15, wherein the performing of the surface modification process comprises an Ar sputtering process.

17. A transfer unit comprising:
a transfer hand having a first surface and a second surface opposing each other;
a slow discharge layer on the first surface, the slow discharge layer is configured to discharge static electricity;
a protrusion on the second surface;
an arm on the protrusion; and
a connector directly contacting the arm and the protrusion.

18. The transfer unit according to claim 17, wherein the slow discharge layer comprises a material having a greater resistivity than a material of the transfer hand.

19. The transfer unit according to claim 17, wherein the transfer hand comprises a dissipative material layer.

20. The transfer unit according to claim 17, wherein:
The connector extends partially through a thickness of the transfer hand while extending entirely through thicknesses of the arm and the protrusion;
the transfer hand has a first thickness;
a minimum distance between the first surface and the connector is a second thickness; and
the second thickness is greater than about half of the first thickness.

21-26. (canceled)
